(19) United States
(12) Patent Application Publication
(10) Pub. No.: US 2026/0133426 A1
(43) Pub. Date: May 14, 2026

(54) FORMULATION

(71) Applicant: Merck Patent GmbH, Darmstadt (DE)

(72) Inventors: Simon Siemianowski, Rossdorf (DE); Frank Voges, Bad Duerkheim (DE)

(21) Appl. No.: 19/379,219

(22) Filed: Nov. 4, 2025

Related U.S. Application Data
(60) Provisional application No. 63/719,565, filed on Nov. 12, 2024.

(51) Int. Cl. G02B 27/01; G02B 6/34

(52) U.S. Cl. CPC G02B 27/0172; G02B 6/34

(57) ABSTRACT

The present invention relates to a method for fabricating an optical waveguide comprising following steps (A) to (D),
(A) Selecting metal oxide precursor materials, or mixtures of metal oxide precursor materials, such that even when multiple cured films are produced separately, and exhibit differing refractive index (RI) values at 530 nm within the range of 1.7 to 2.3, preferably 1.8 to 2.2, the ratio of the refractive index at 450 nm (R450) to that at 630 nm (R630) consistently remains between 1.015 and 1.045, preferably between 1.015 and 1.040;
(B) preparing a formulation containing the selected metal oxide precursor or the mixture of the metal oxide precursors;
(C) providing the formulation obtained in step (B) over a surface of a substrate to form a curable composite, preferably by wet deposition process, more preferably by spin-coating or ink-jetting, even more preferably by ink-jetting; and
(D) curing the formulation, preferably by heat, by UV irradiation to obtain a cured composite.

Obtained optical waveguides may be used in display device applications, for example a Liquid crystal display (LCD), Light emitting diode display (LED display), organic light emitting display (OLED), micro-LED display, quantum dot display (QLED), AR display, VR display, MR display, plasma (PDP) display, electroluminescent (ELD) display fabricated on a substrate controlled by semiconductors.

### RELATED APPLICATIONS

The present application claims the benefit of priority of U.S. Provisional Application No. 63/719,565, filed Nov. 12, 2024, the contents of which are incorporated herein by reference in their entirety.

### FIELD OF THE INVENTION

The present application relates to a method for fabricating an optical waveguide, an optical waveguide, and a display device.

### BACKGROUND OF THE INVENTION

The design and manufacture of surface relief gratings (SRG) is key to the performance of future AR/VR, MR headsets, typically AR headsets. The design layout and choice of materials within a SRG is carefully optimized by companies to try to find a balance between parameters such as field of view, efficiency (power usage), brightness and cost. A conventional SRG consists of three layers, namely, a substrate, a structured layer (produced either via ion beam lithography or NIL), and then a third gap fill layer.

Since most AR displays use a light engine that consists of the three primary colors, RGB, then the control of dispersion within the waveguide must be considered. Without control of dispersion then each of the wavelengths would be diffracted by varying amounts, leading to poor color uniformity in the resulting image. This is a common issue in AR displays and is usually observed as red or blue shifted colors on the outer edges of the field of view.

In the coming years, the trend for AR/VR and MR displays is to increase the refractive index of the substrate to allow more light to be coupled into a single-layer waveguide and to achieve a larger theoretical field of view. This means that dispersion control will become even more important.

Materials need to be available for waveguide design that have a range of dispersion values. In particular, it is highly advantageous to have materials with intrinsically low dispersion, since this would automatically improve optical quality without the need for complex balancing of diffraction by subsequent layers in the waveguide. Unfortunately, there is a fundamental relationship between refractive index and dispersion, both for organic and inorganic material systems. Materials with higher refractive index also have higher dispersion.

Given this context, in discussions about materials for constructing and creating alternative optical waveguides, metal oxide nanoparticles have been found to serve as both modifiers and rigid building blocks for nanostructures made using nanoimprint lithography. [DOI: 10.1051/epjap/2012120166; 10.1038/s41467-020-16136-5]

A typical nanoimprint procedure involves dispensing a metal oxide (or other type of) nanoparticle containing ink onto a substrate via, e.g., spin coating or ink jet printing and bringing the resulting thin liquid film in contact with a mold. The action of capillary forces allows the ink to fill the mold's nanosized cavities. The following curing step causes a change in colloidal stability of the nanoparticle ink through different mechanisms that result in interparticle crosslinking while the solvent can be removed by gradual diffusion and evaporation provided the mold is made from a porous material. The curing process is driven either thermally or preferentially by continuous or pulsed high intensity ultraviolet irradiation, preferentially at a wavelength of 365 nm.

The mechanisms of nanoparticle crosslinking include i) direct sintering resulting from the complete or partial breakdown of capping ligands at the nanoparticle surface that is caused by highly energetic and redox reactive electron-hole pair states populated by UV absorption of the metal oxide particle core, ii) crosslinking through capping ligands that typically contain olefinic functional groups and/or, iii) chemical conversion of an added bonding agent to form a homogenous and amorphous inorganic material acting as a glue. The bonding agent can also comprise precursors used for metal oxide nanoparticle synthesis (US 2014072720 A2), (US 2019243237 A2). Notably, pathways ii and iii can also start from reactive excited states populated through the absorption of UV light by the metal oxide nanoparticle core.

Titanium dioxide, TiO₂, has found widespread use as a material for direct photocuring in the prior art, for its bandgap allows electronic absorption in the 365 nm region and the excited state lifetime matches the timescale of the chemical reactions that underly afore described three pathways toward interparticle bonding. Notably, the deposition of thin and dense films comprising TiO₂ in form of at least one of the known crystal morphologies was pointed out as a prerequisite for achieving effective photocuring activity (US 2007267764 A2).

The use of thin titania films has been claimed for UV light driven self- and pre-cleaning of substrate or mold surfaces, with TiO₂ acting as an anti-sticking layer in the latter case (US 2010109205 A2).

TiO₂ films have been deposited via gas phase deposition and sol-gel approaches that require an elevated temperature curing step for conversion into anatase (500° C.) or rutile (700° C.) forms (US 2015322286 A2). Another remarkable approach uses commercial colloids of crystalline, surface modified TiO₂ nanoparticles as building blocks for direct UV nanoimprinting (UV-NIL) of several types of meta-surfaces (US 2019243237 A2).

While the latter strategy may be generalized to any nanomaterial showing electronic absorption at 365 nm and effective excited state reactivity, photocorrosion to adjacent layers of organic material is a severe downside that can cause device failure. This shortcoming has been overcome by means of surface modification of high band gap metal oxide, e.g., ZrO₂, nanoparticles with bonding/coupling agents comprising olefinic or other types of organic functional groups that crosslink effectively in the presence of radicals generated from exposure to UV light (US 2013078796 A2).

### Patent Literature

1. US 2014072720 A2
2. US 2019243237 A2
3. US 2007267764 A2
4. US 2010109205 A2
5. US 2015322286 A2
6. US 2019243237 A2
7. US 2013078796 A2

### Non-Patent Literature

8. DOI: 10.1051/epjap/2012120166; 10.1038/s41467-020-16136-5

### SUMMARY OF THE INVENTION

The inventors newly have found that there are still one or more of considerable problems for which improvement is desired, as listed below: Improving Color Uniformity: Achieving consistent color uniformity in waveguides to enhance overall visual performance.

Finding Low Dispersion Materials: Identifying intrinsically low dispersion materials, such as metal oxide precursors, that perform well at high refractive indices after curing.

Maintaining Optical Properties: Ensuring that the selected materials maintain their optical properties even when subjected to varying process conditions.

Creating Optical Functional Components: Developing optical functional components of the waveguide that exhibit a refractive index (RI) range of 1.7 to 2.3 at 520 nm.

Ensuring Stability Across the Spectrum: Guaranteeing that the manufactured optical waveguides have stable optical structures with minimal changes in RI values across the visible light spectrum, especially between 450 nm and 630 nm.

Material Selection and Optimization: Prioritizing the identification and selection of suitable materials that meet the above criteria for effective waveguide performance.

Fabricating an optical waveguide using a formulation that exhibits reduced or no photocorrosion induced by the deposited optical layer while keeping good UV photocuring properties of said layer, preferably by irradiation at around 365 nm;

Fabricating an optical waveguide using a formulation that prevents aggregation of mixture of oxide nanoparticle(s) in the formulation, allow processing in form of transparent colloids in the formulation, in an organic solvent, polymer matrix material and/or polymerizable organic monomer(s); effectively detach/remove any capping ligand(s) from the surface of said mixture of metal oxide nanoparticles by UV photocuring or UV induced decomposition, preferably at around 365 nm light wavelength of UV light photocuring; effectively change the colloidal stability of said mixture metal oxide nanoparticles by UV photocuring, preferably at around 365 nm light wavelength of UV light photocuring; providing a suitable ink formulation for UV-Nanoimprinting (UV-NIL) process, without or less causing aggregation of the mixture of metal oxide nanoparticles, with keeping good UV photocuring properties, leading to less or no UV photocorrosion problems namely at 365 nm light wavelength. Additionally, provide an optical waveguide created using such materials and methods.

The inventors aimed to solve one or more of the above-mentioned problems.

Then, the present inventors have surprisingly found that one or more of the above-described technical problems can be solved by the features as defined in the claims.

Namely, it is found a new method for fabricating an optical waveguide comprising, essentially consisting of or consisting of, following steps (A) to (D),
(A) Selecting metal oxide precursor materials, or mixtures of metal oxide precursor materials, such that even when multiple cured films are produced separately (under different manufacturing conditions), and exhibit differing refractive index (RI) values at 530 nm within the range of 1.7 to 2.3, preferably 1.8 to 2.2, the ratio of the refractive index at 450 nm (R450) to that at 630 nm (R630) consistently remains between 1.015 and 1.045, preferably between 1.015 and 1.040;
(B) preparing a formulation containing the selected metal oxide precursor or the mixture of the metal oxide precursors;
(C) providing the formulation obtained in step (B) over a surface of a substrate to form a curable composite, preferably by wet deposition process, more preferably by spin-coating or ink-jetting, even more preferably by ink-jetting; and
(D) curing the formulation, preferably by heat, by UV irradiation to obtain a cured composite.

In another aspect, the invention further relates to an optical waveguide comprising one or more of optical gratings and optionally said one or more optical gratings is at least partly filled with a metal oxide; wherein
1) said optical gratings have the refractive index value at 530 nm falls within the range of 1.7 to 2.3, preferably 1.8 to 2.2, and the ratio of the refractive index at 450 nm (R450) to the refractive index at 630 nm (R630) is between 1.015 and 1.045, preferably 1.015 and 1.040; and/or
2) one or more optical gratings is at least partly filled with a metal oxide and said metal oxide has the refractive index value at 530 nm falls within the range of 1.7 to 2.3, preferably 1.8 to 2.2, and the ratio of the refractive index at 450 nm (R450) to the refractive index at 630 nm (R630) is between 1.015 and 1.045, preferably 1.015 and 1.040.

In another aspect, the invention also relates to a display device comprising, essentially consisting of or consisting of, at least one functional medium configured to direct and modulate a light or configured to emit light; and the optical waveguide of the present invention.

### Technical Effects of the Invention

The present invention may provide one or more of following effects; Improving Color Uniformity: Achieving consistent color uniformity in waveguides to enhance overall visual performance.

Finding Low Dispersion Materials: Identifying intrinsically low dispersion materials, such as metal oxide precursors, that perform well at high refractive indices after curing.

Maintaining Optical Properties: Ensuring that the selected materials maintain their optical properties even when subjected to varying process conditions.

Creating Optical Functional Components: Developing optical functional components of the waveguide that exhibit a refractive index (RI) range of 1.7 to 2.3 at 520 nm.

Ensuring Stability Across the Spectrum: Guaranteeing that the manufactured optical waveguides have stable optical structures with minimal changes in RI values across the visible light spectrum, especially between 450 nm and 630 nm.

Material Selection and Optimization: Prioritizing the identification and selection of suitable materials that meet the above criteria for effective waveguide performance.

Fabricating an optical waveguide using a formulation that exhibits reduced or no photocorrosion induced by the deposited optical layer while keeping good UV photocuring properties of said layer, preferably by irradiation at around 365 nm;

Fabricating an optical waveguide using a formulation that exhibits reduced or no photocorrosion induced by the deposited optical layer while keeping good UV photocuring properties of said layer, preferably by irradiation at around 365 nm;

Fabricating an optical waveguide using a formulation that prevents aggregation of mixture of oxide nanoparticle(s) in the formulation, allow processing in form of transparent colloids in the formulation, in an organic solvent, polymer matrix material and/or polymerizable organic monomer(s); effectively detach/remove any capping ligand(s) from the surface of said mixture of metal oxide nanoparticles by UV photocuring or UV induced decomposition, preferably at around 365 nm light wavelength of UV light photocuring; effectively change the colloidal stability of said mixture metal oxide nanoparticles by UV photocuring, preferably at around 365 nm light wavelength of UV light photocuring; providing a suitable ink formulation for UV-NIL process, without or less causing aggregation of the mixture of metal oxide nanoparticles, with keeping good UV photocuring properties, leading less or no UV photocorrosion problems namely at 365 nm light wavelength. Additionally, provide an optical waveguide created using such materials and methods.

### BRIEF DESCRIPTION OF THE FIGURES

FIG. 1: The summary of dispersion plots of R450/R630 ratio measurements calculated for each film based on its RI at 530 nm of the working example.

### DEFINITION OF THE TERMS

In the context of the present invention, the term “ligand” as used herein, refers to an ion or molecule attached to a metal atom by coordinate bonding.

The term “surfactant” as used herein, refers to an additive that reduces the surface tension of a given formulation.

The term “wetting and dispersion agent” as used herein, refers to an additive that increases the spreading and filling properties of a given formulation. In this way, the tendency of the molecules to adhere to each other is reduced.

The term “adhesion promoter” as used herein, refers to an additive that increases the adhesion of a given formulation.

The term “optical medium” is a nanostructure or nanostructures including nanosized optical gratings, or any other patterned or random nano-sized uneven structures fabricated on a substrate, lenses, prisms, mirrors, optical windows, filters, polarizing optics, UV and IR optics, waveguides and optical coatings. In other words, optical medium of the present invention may be a nanostructure or nanostructures of an optical device of the present invention and it is a part of an optical device of the present invention.

The term “display device” as used herein, is a kind of an optical device configured to output/present information in visual or tactile form. Examples are Liquid crystal display (LCD), Light emitting diode display (LED display), organic light emitting display (OLED), micro-LED display, quantum dot display (QLED), AR display, VR display, MR display, plasma (PDP) display, electroluminescent (ELD) display. Preferred optical devices in the context of the present invention is AR display, VR display or MR display.

### DETAILED DESCRIPTION OF THE INVENTION

Hereinafter, embodiments of the present invention are described in detail.

### [Method for Fabricating an Optical Waveguide]

According to the present invention, method for fabricating an optical waveguide comprises, essentially consists of or consists of, following steps (A) to (D),
(A) Selecting metal oxide precursor materials, or mixtures metal oxide precursor materials, such that even when multiple cured films are produced separately (under different manufacturing conditions), and exhibit differing refractive index (RI) values at 530 nm within the range of 1.7 to 2.3, preferably 1.8 to 2.2, the ratio of the refractive index at 450 nm (R450) to that at 630 nm (R630) consistently remains between 1.015 and 1.045, preferably between 1.015 and 1.040;
(B) preparing a formulation containing the selected metal oxide precursor or the mixture of the metal oxide precursors;
(C) providing the formulation obtained in step (B) over a surface of a substrate to form a curable composite, preferably by wet deposition process, more preferably by spin-coating or ink-jetting, even more preferably by ink-jetting; and
(D) curing the formulation, preferably by heat and/or by UV irradiation to obtain a cured composite.

It is believed that by using the above method, even when creating an optical waveguide with optical structures that have varying RI values in the range of 1.7 to 2.3, preferably from 1.8 to 2.2 at 530 nm by changing process conditions (such as optical structures of an optical waveguide having RI 1.8 at 530 nm, RI 2.0 at 530 nm or RI 2.2 at 530 nm), it is always possible to manufacture an optical waveguide with stable optical structures that exhibit minimal changes in RI values across the entire visible light spectrum, particularly in the range of 450 nm to 630 nm.

In other words, it is believed to consistently manufacture an optical waveguide with stable optical structures that exhibit minimal changes in RI values across the entire visible light spectrum, particularly in the range of 450 nm to 630 nm, regardless of variations in manufacturing conditions. This leads to improved color uniformity in the resulting image in optical display devices such as AR, VR, and/or MR display devices.

### Selection Process

The materials selected in step (A) can be chosen through the following selection process, and optionally the method for fabricating an optical waveguide of the present invention comprises the following selection process (X) before step (A). The results of the selection process

### Selection Process (X)

Selection process (X) of the present invention comprises, essentially consists or consists of the following steps (XB) to (XD) in this order:
(XB) Preparing a formulation by mixing at least one solvent and either a metal oxide precursor or a mixture of metal oxide precursors to test whether the metal oxide precursor or the mixture of metal oxide precursors meets the conditions of Step (A) in the above method;
(XC) providing the formulation obtained in step (XB) onto a surface of a substrate to form a curable composite by spin-coating or ink-jetting, even more preferably by ink-jetting, preferably said substrate is optically transparent in visible wavelength, such as glass substrate;
(XE) optionally applying pre-baking; and
(XD) curing the formulation, preferably by heat and/or by UV irradiation to obtain a cured composite.

Preferably, any publicly known metal-oxide precursor for NIL imprinting or gap-filling in the fabrication of optical waveguides for AR/VR/MR/XR devices may be used, either individually or in combination with other publicly known metal-oxide precursors, in the selection process (X), specifically in step (XB).

The RI value of the obtained film at 530 nm can be varied within the range of 1.7 to 2.3, preferably from 1.8 to 2.2, primarily by adjusting the following process conditions: the presence or absence of soft bake and its baking temperature, the presence or absence of hard bake and its baking temperature, spin coating speed, solvent choice, and the solid concentration of the metal oxide precursor or a mixture of metal oxide precursors to test whether the metal oxide precursor or the mixture meets the conditions of Step (A).

Conditions that affect the RI value of the film at 530 nm, such as the type of solvent, pre-baking temperature, hard-baking temperature, and UV irradiation conditions, can be appropriately selected and implemented by those skilled in the art based on the descriptions in the examples of this specification and common technical knowledge. Preferably, these can be selected and executed as appropriate based on the examples and specified criteria.

In the selection process, the data obtained—namely, the ratio of the refractive index at 450 nm (R450) to that at 630 nm (R630)—is assigned to each used metal-oxide precursor material and stored in a database organized by the refractive index at 530 nm. By referencing this database, selection may be performed in Step (A). Alternatively, a user may input into a computer the desired type of metal-oxide precursor, whereupon the system consults the database to automatically propose candidates and then carries out selection either automatically or manually according to other preset conditions.

### Measurement Method for the RI Values of the Obtained Film Samples

According to the present invention, Ellipsometry is used to determine layer thickness, refractive index (n) and absorption index (k) of a metal oxide layer as shown in working examples. Measurements are performed using an ellipsometer M2000 from J. A. Woolam and three different angles of incidence (65°, 70° and 75°). The measurement data is analyzed with software CompleteEase from J. A. Woolam, applying a Gen-Osc fitting model for obtaining refractive index (n) as well as absorption index (k). The optical constants are averaged from five measured points on each film.

In some embodiments of the present invention, said substrate contains optical gratings on the surface of the substrate and said cured composite fills at least some of the gaps in the optical gratings.

In a preferred embodiment where said substrate contains optical gratings on the surface of the substrate and said cured composite fills at least some of the gaps in the optical gratings, said formulation comprises at least; (i) a metal oxide precursor material selected from Tantalum chloride, Tantalum ethoxide, Niobium chloride, niobium ethoxide or an any combination of Tantalum chloride, Tantalum ethoxide, Niobium chloride, niobium ethoxide, preferably said any combination is being a combination of Tantalum chloride and Niobium chloride, or a combination of Niobium chloride and Niobium ethoxide.

In a preferred embodiment of the present invention, said cured composite obtained in step (D) is being one or more of optical gratings of the optical waveguide, and
wherein following step (E) is applied before step (D) after step (C), and step (D) consists of following steps (D1) and (F) to form said optical gratings:
(E) pressing a mold against said curable composite formed on the substrate;
(D1) irradiating the curable composite with UV light, preferably at around 365 nm to form a cured composite; and
(F) optionally applying a thermal treatment to remove any organic component,
and optionally in step (F), the temperature of the thermal treatment in the range from 50 to 650° C., preferably it is from 80 to 200° C., more preferably from 100 to 150° C., is applied, optionally, in step (F), a UV cured composite obtained by step (D1) is heated from the room temperature to the temperature in the range from 200 to 600° C.

In some embodiments in step (D1), the photocuring at 365 nm wavelength of light effectively causes aggregation and solidification of said another metal oxide nanoparticle whereas photocuring is ineffective for said Nb oxide nanoparticle, which still may be removed by a solvent rinse or gentle rubbing. In other words, the resulting film is not mechanically persistent after photocuring.

Preferably, the method further comprises step (o) before step (A);
(o) substituting the solvent of the formulation of the present invention with another solvent or a solvent mixture.

In a preferred embodiment where said cured composite obtained in step (D) is being one or more of optical gratings of the optical waveguide, said formulation comprises at least;
i) a Nb oxide nanoparticle, preferably said Nb oxide nanoparticle is a surface-modified Nb oxide nanoparticle or colloidally stable Nb oxide nanoparticle, preferably said formulation contains a plurality of Nb oxide nanoparticles;
ii) optionally another metal oxide nanoparticle that is not a Nb oxide nanoparticle, preferably said another metal oxide nanoparticle is a surface-modified or colloidally stable metal oxide nanoparticle, preferably the formulation contains said another metal oxide nanoparticle, preferably said formulation contains a plurality of another metal oxide nanoparticles; and
iii) a solvent,
   wherein said another metal oxide nanoparticle comprises a metal element selected from the group consisting of group 4 elements of the periodic table, group 12 elements of the periodic table, group 14 elements of the periodic table, preferably said group 4 element is Ti, said group 12 element is Zn, or said group 14 element is Sn;
optionally said Nb oxide nanoparticle is a surface-modified Nb oxide nanoparticle or colloidally stable Nb oxide nanoparticle, having an alkoxysilane as a surface capping ligand or polymerizable functional group, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, preferably said polymerizable functional group is selected from the group consisting of a vinyl group, (meth)acrylic group, epoxy group, a mercapto group, even more preferably said polymerizable functional group is a (meth)acrylic group;
optionally said another metal oxide nanoparticle is a surface-modified or colloidally stable metal oxide nanoparticle having an alkoxysilane as a surface capping ligand or polymerizable functional group, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, preferably said polymerizable functional group is selected from the group consisting of a vinyl group, (meth)acrylic group, epoxy group, a mercapto group, even more preferably said polymerizable functional group is a (meth)acrylic group;
optionally said solvent is an organic solvent, preferably said organic solvent is selected from one or more members of the group consisting of alcohols, glycols, ethers, ketones, esters, hydrocarbons, aromatic hydrocarbons, amides and sulfones. More preferably said organic solvent is selected from one or more members of the group consisting of ethylene glycol monoalkyl ethers, preferably it is ethylene glycol monomethyl ether, ethylene glycol monoethyl ether, ethylene glycol monopropyl ether and/or ethylene glycol monobutyl ether; diethylene glycol dialkyl ethers, preferably it is diethylene glycol dimethyl ether, diethylene glycol diethyl ether, diethylene glycol dipropyl ether and/or diethylene glycol dibutyl ether; propylene glycol monoalkyl ethers, preferably it is propylene glycol monomethyl ether (PGME), propylene glycol monoethyl ether and/or propylene glycol monopropyl ether; ethylene glycol alkyl ether acetates, preferably it is methyl cellosolve acetate and/or ethyl cellosolve acetate; propylene glycol alkyl ether acetates, preferably it is propylene glycol monomethyl ether acetate (PGMEA), propylene glycol monoethyl ether acetate and/or propylene glycol monopropyl ether acetate; 2-(2-butoxyethoxy)ethyl acetate; ketones, preferably it is methyl ethyl ketone, acetone, methyl amyl ketone, methyl isobutyl ketone and/or cyclohexanone; alcohols, preferably it is ethanol, propanol, 1,3-dimethoxy-2-propanol, butanol, hexanol, cyclo hexanol, ethylene glycol, propylene glycol, triethylene glycol, glycerin, pentanols, preferably it is 1-pentanol, 2-pentnol, 3-pentanol, 3-ethyl-3-pentanol, 2,4-dimethyl-3-pentanol; esters, preferably it is ethyl 3-ethoxypropionate, methyl 3-methoxypropionate and/or ethyl lactate; and cyclic esters, preferably it is gamma-butyro-lactone; preferably said solvent is selected from propylene glycol alkyl ether acetates, ethylene glycol monoalkyl ethers, propylene glycol and propylene glycol monoalkyl ethers, 1-pentanol, 2-pentnol, 3-pentanol, 3-ethyl-3-pentanol, 2,4-dimethyl-3-pentanol 1,3-dimethoxy-2-propanol or a mixture of any one of them.

In a preferred embodiment of the present invention, said another metal oxide nanoparticle is a TiO₂, ZnO or SnO₂ nanoparticle optionally having one or more surface capping ligands, which can be either chemically bonded to the nanoparticle surface or function as physically interacting additives to enhance stability and performance, optionally, said TiO₂ nanoparticle, ZnO nanoparticle, or SnO₂ nanoparticle are amorphous nanoparticles or crystalline nanoparticles, more preferably said another oxide nanoparticle is a surface modified TiO₂ nanoparticle having surface capping ligands as a surface modifier.

Preferably, the mass ratio of the another metal oxide nanoparticles to the Nb oxide nanoparticles is within the range from 1:1 to 1:99, preferably it is within the range from 3:7 to 1:49, more preferably from 1:4 to 1:19.

In some embodiments of the present invention where said cured composite obtained in step (D) is being one or more of optical gratings of the optical waveguide, the formulation further comprises a matrix material selected from one or more members of the group consisting of a silicone resin, an acrylic resin, an epoxy resin, an olefin resin, a polysulfide resin, a polythiol-urethane resin, polycarbonate resin, a polyamide resin, a polyester resin, a polyphenylene ether resin and a polyarylene sulfide resin. Preferably said matrix material is transparent in visible light wavelength.

Preferably said matrix material is an acrylate resin, an epoxy resin or a mixture of an acrylate resin and an epoxy resin.

### [Alkoxysilane]

In a preferred embodiment of the present invention, said alkoxysilane is a silane coupling agent or tetraalkoxysilane, more preferably it is a silane coupling agent that contains an aliphatic hydrocarbon having at least 4 carbon atoms or aromatic hydrocarbon, polyethylene glycol, and/or a fluorocarbon, polymerizable functional group;
preferably said polymerizable functional group is selected from the group consisting of a vinyl group, (meth)acrylic group, epoxy group, a mercapto group, even more preferably said polymerizable functional group is a (meth)acrylic group.

In one embodiment, the alkoxysilane may be represented by formula (c1).

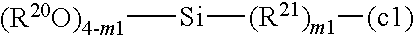

wherein m1 is 0, 1, 2 or 3, preferably 1;
R²⁰ is a straight-chain alkyl having 1 to 15 carbon atoms, preferably 1 to 10 carbon atoms, more preferably 1 to 5 carbon atoms, very preferably 1 to 3 carbon atoms; a branched or cyclic structure-containing alkyl having 3 to 15 carbon atoms, preferably 3 to 10 carbon atoms, more preferably 3 to 5 carbon atoms; an aryl having 6 to 20 carbon atoms, preferably 6 to 15 carbon atoms, more preferably 6 to 10 carbon atoms, (meth)acrylate group; wherein one or more non-adjacent CH₂ may be replaced by O, S, CO, CO—O, O—CO, C═O, O—CO—O, CR²²═CR²³ or C≡C;
R²² and R²³ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more H may be replaced by OH, COOH, a straight-chain alkyl having 1 to 6 carbon atoms, a branched or cyclic structure-containing alkyl having 3 to 6 carbon atoms;
wherein R²¹ is a straight-chain alkyl having 1 to 25 carbon atoms, preferably 1 to 15 carbon atoms, more preferably 1 to 10 carbon atoms; a branched or cyclic structure-containing alkyl having 3 to 25 carbon atoms, preferably 3 to 15 carbon atoms, more preferably 3 to 10 carbon atoms; a straight-chain alkenyl having 1 to 25 carbon atoms, preferably 1 to 15 carbon atoms, more preferably 1 to 10 carbon atoms; a branched or cyclic structure-containing alkenyl having 3 to 25 carbon atoms, preferably 3 to 15 carbon atoms, more preferably 3 to 10 carbon atoms; an aryl having 6 to 25 carbon atoms, preferably from 6 to 15 carbon atoms, more preferably 6 to 10 carbon atoms;
wherein one or more non-adjacent CH₂ may be replaced by O, S, CO, CO—O, O—CO, O—CO—O, CR²⁴═CR²⁵, C═CR²⁴R²⁵, or C≡C, preferably replaced by O—CO;
wherein R²⁴ and R²⁵ are each independently H, a straight-chain alkyl having 1 to 25 carbon atoms, preferably 1 to 15 carbon atoms, more preferably 1 to 10 carbon atoms; a branched or cyclic structure containing alkyl having 3 to 25 carbon atoms, preferably 3 to 15 carbon atoms, more preferably 3 to 10 carbon atoms; an aryl having 6 to 25 carbon atoms, preferably 6 to 15 carbon atoms, more preferably 6 to 10 carbon atoms, very preferably R²⁴ and R²⁵ are H;
wherein one or more H may be replaced by OH, COOH, a straight-chain alkyl having 1 to 6 carbon atoms, a branched or cyclic structure-containing alkyl having 3 to 6 carbon atoms.

In a preferred embodiment, R²¹ may be straight or branched alkyl group, branched or cyclic structure-containing alkyl group, (meth)acryl group.

It is believed that such alkoxysilane may prevent aggregation of Nb oxide nanoparticle and/or another metal oxide nanoparticle(s) in the formulation, allow processing Nb oxide nanoparticles and/or another metal oxide nanoparticles in form of colloidal formulations, in an organic solvent, polymer matrix material and/or polymerizable organic monomer(s). It is also believed that such alkoxysilane may be effectively detached/removed from the surface of said Nb oxide and/or another metal oxide nanoparticle(s) by UV photocuring and/or decomposed by UV photocuring.

Thus, in a preferred embodiment of the present invention, said surface modified another metal oxide nanoparticle has or interacts with a hydrolyzed alkoxysilane as a surface capping ligand or surface stabilizing additive, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, polymerizable functional group;
said surface modified Nb oxide nanoparticle has an alkoxysilane as a surface capping ligand, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, polymerizable functional group;
preferably said polymerizable functional group is selected from the group consisting of a vinyl group, (meth)acrylic group, epoxy group, a mercapto group, even more preferably said polymerizable functional group is a (meth)acrylic group.

As for such alkoxysilane, publicly available ones like disclosed in US 2013/016444 A1 can be used preferably, including 3-(trimethoxysilyl)propyl methacrylate and octyltriethoxysilane.

For examples, said metal oxide nanoparticles (surface-modified Nb oxide nanoparticle, surface-modified or colloidally stable another metal oxide nanoparticle) with alkoxysilane may be obtained by a publicly known method like described in US 2013/016444 A1.

In a preferred embodiment of the present invention, the relative molar quantities of metal oxide (M) and hydrolysable main group metal element (E) such as Si of the surface capping ligand or stabilizing additive precursor is M:E≥4, more preferably M:E≥200, even more preferably M:E≥400; and preferably it is M:E≤1500, more preferably M:E≤1200, even more preferably ≤1200. Thus, preferably said relative molar quantities of metal oxide (M) and Si atom of the surface capping ligand or stabilizing additive precursor (E) M:E is in the range from 4 to 1500. More preferably from 200 to 1200. Even more preferably from 400 to 1000.

It is believed that this mixing ratio may effectively reduce or prevent issues related to photocorrosion while maintaining good UV photocuring properties of the materials (including Nb oxide nanoparticles and another metal oxide nanoparticles, and optionally matrix materials) in the formulation.

In a preferred embodiment of the present invention, the average diameter size of said Nb oxide nanoparticle(s) and/or another metal oxide nanoparticle(s) (excluding capping ligands and any surface-interacting hydrolyzed main group metalorganic additives) is in the range from 1 nm to 100 nm.

Said average diameter may be determined by taking SEM images and measuring the longest diameter of 100 nanoparticles to calculate the average size. This method allows for a detailed observation of the nanoparticle shapes and size distribution.

It is believed that it is preferably for ink jetting or spin coating, it may lead to a good refractive index value such as more than 2.0, and/or it may exhibit more dense film or dense optical grating for an optical waveguide by nanoimprint lithography after curing.

In a preferred embodiment of the present invention, said surface modified another metal oxide nanoparticle has an alkoxysilane as a surface capping ligand, which may include both chemically bonded ligands and physically interacting additives to enhance stability and performance, or hydrolysable main group metalorganic additive, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, polymerizable functional group;
said surface modified Nb oxide nanoparticle is colloidally stabilized by means of a hydrolysable main group metalorganic additive or a surface capping ligand, preferably an alkoxysilane, said alkoxysilane is a silane coupling agent or tetraalkoxysilane, more preferably it is a silane coupling agent an aliphatic hydrocarbon having at least 4 carbon atoms or aromatic hydrocarbon, polyethylene glycol, and/or a fluorocarbon, polymerizable functional group;
preferably said polymerizable functional group is selected from the group consisting of a vinyl group, (meth)acrylic group, epoxy group, a mercapto group, even more preferably said polymerizable functional group is a (meth)acrylic group.

According to the present invention, as a preferable embodiment, the another metal oxide nanoparticle(s) and the Nb oxide nanoparticle(s) constitute 0.1 wt % to 50 wt % of the formulation, preferably it is from 1 wt. % to 30 wt. %, more preferably from 5 to 20 wt. %.

It is believed that it enables to provide a suitable ink formulation for UV-NIL process, without or less causing aggregation of the Nb oxide nanoparticle and another metal oxide nanoparticles, with keeping good UV photocuring properties, leading less or no UV photocorrosion problems namely at 365 nm light wavelength.

### [Solvent]

It is believed that the above mentioned solvents are preferable for wet printing process e.g. inkjetting or spin coating also suitable for NIL process including UV nanoimprint lithography (UV-NIL), thermal nanoimprint lithography (TNIL) and a combination of UV-NIL and TNIL. Preferably it is suitable for at least UV-NIL process.

### [Matrix Material]

In a preferred embodiment of the present invention, said formulation may further comprises a matrix material selected from one or more members of the group consisting of a silicone resin, an acrylic resin, an epoxy resin, an olefin resin, a polysulfide resin, a polythiol-urethane resin, polycarbonate resin, a polyamide resin, a polyester resin, a polyphenylene ether resin and a polyarylene sulfide resin. Preferably said matrix material is transparent in visible light wavelength.

Preferably said matrix material is an acrylate resin, an epoxy resin or a mixture of an acrylate resin and an epoxy resin. It is believed that these are transparent in visible light wavelength and preferable for fabricating an optical medium such as optical gratings for waveguide. Namely these are preferable for wet printing process e.g. ink-jetting or spin coating also suitable for NIL process including UV nanoimprint lithography (UV-NIL), thermal nanoimprint lithography (TNIL) and a combination of UV-NIL and TNIL. Preferably it is suitable for at least UV-NIL process.

### Optical Waveguide

The present invention further relates to an optical waveguide comprising one or more of optical gratings and optionally said one or more optical gratings is at least partly filled with a metal oxide; wherein
1) said optical gratings have the refractive index value at 530 nm falls within the range of 1.7 to 2.3, preferably 1.8 to 2.2, and the ratio of the refractive index at 450 nm (R450) to the refractive index at 630 nm (R630) is between 1.015 and 1.045, preferably 1.015 and 1.040; and/or
2) one or more optical gratings is at least partly filled with a metal oxide and said metal oxide has the refractive index value at 530 nm falls within the range of 1.7 to 2.3, preferably 1.8 to 2.2, and the ratio of the refractive index at 450 nm (R450) to the refractive index at 630 nm (R630) is between 1.015 and 1.045, preferably 1.015 and 1.040.

In a preferred embodiment of the present invention, said optical waveguide is obtained by the method for fabricating an optical waveguide of the present invention as described above.

In another preferred embodiment of the present invention, said optical gratings are made from the formulation comprising at least;
i) a Nb oxide nanoparticle, preferably said Nb oxide nanoparticle is a surface-modified metal oxide nanoparticle or colloidally stable metal oxide nanoparticle, preferably said formulation contains a plurality of Nb oxide nanoparticles;
ii) optionally another metal oxide nanoparticle that is not a Nb oxide nanoparticle, preferably said another metal oxide nanoparticle is a surface-modified or colloidally stable metal oxide nanoparticle; and
iii) a solvent;
   wherein said another metal oxide nanoparticle comprises a metal element selected from the group consisting of group 4 elements of the periodic table, group 12 elements of the periodic table, group 14 elements of the periodic table, preferably said group 4 element is Ti, said group 12 element is Zn, or said group 14 element is Sn;
optionally said Nb oxide nanoparticle is a surface-modified Nb oxide nanoparticle or colloidally stable Nb oxide nanoparticle, having an alkoxysilane as a surface capping ligand or polymerizable functional group, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, preferably said polymerizable functional group is selected from the group consisting of a vinyl group, (meth)acrylic group, epoxy group, a mercapto group, even more preferably said polymerizable functional group is a (meth)acrylic group;
optionally said another metal oxide nanoparticle is a surface-modified or colloidally stable metal oxide nanoparticle having an alkoxysilane as a surface capping ligand or polymerizable functional group, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, preferably said polymerizable functional group is selected from the group consisting of a vinyl group, (meth)acrylic group, epoxy group, a mercapto group, even more preferably said polymerizable functional group is a (meth)acrylic group;
optionally said solvent is an organic solvent, preferably said organic solvent is selected from one or more members of the group consisting of alcohols, glycols, ethers, ketones, esters, hydrocarbons, aromatic hydrocarbons, amides and sulfones. More preferably said organic solvent is selected from one or more members of the group consisting of ethylene glycol monoalkyl ethers, preferably it is ethylene glycol monomethyl ether, ethylene glycol monoethyl ether, ethylene glycol monopropyl ether and/or ethylene glycol monobutyl ether; diethylene glycol dialkyl ethers, preferably it is diethylene glycol dimethyl ether, diethylene glycol diethyl ether, diethylene glycol dipropyl ether and/or diethylene glycol dibutyl ether; propylene glycol monoalkyl ethers, preferably it is propylene glycol monomethyl ether (PGME), propylene glycol monoethyl ether and/or propylene glycol monopropyl ether; ethylene glycol alkyl ether acetates, preferably it is methyl cellosolve acetate and/or ethyl cellosolve acetate; propylene glycol alkyl ether acetates, preferably it is propylene glycol monomethyl ether acetate (PGMEA), propylene glycol monoethyl ether acetate and/or propylene glycol monopropyl ether acetate; 2-(2-butoxyethoxy)ethyl acetate; ketones, preferably it is methyl ethyl ketone, acetone, methyl amyl ketone, methyl isobutyl ketone and/or cyclohexanone; alcohols, preferably it is ethanol, propanol, 1,3-dimethoxy-2-propanol, butanol, hexanol, cyclo hexanol, ethylene glycol, propylene glycol, triethylene glycol, glycerin, pentanols, preferably it is 1-pentanol, 2-pentnol, 3-pentanol, 3-ethyl-3-pentanol, 2,4-dimethyl-3-pentanol; esters, preferably it is ethyl 3-ethoxypropionate, methyl 3-methoxypropionate and/or ethyl lactate; and cyclic esters, preferably it is gamma-butyro-lactone; preferably said solvent is selected from propylene glycol alkyl ether acetates, ethylene glycol monoalkyl ethers, propylene glycol and propylene glycol monoalkyl ethers, 1-pentanol, 2-pentnol, 3-pentanol, 3-ethyl-3-pentanol, 2,4-dimethyl-3-pentanol 1,3-dimethoxy-2-propanol or a mixture of any one of them.

In more preferred embodiment of the present invention, said formulation comprises at least
i) a Nb oxide nanoparticle, preferably said Nb oxide nanoparticle is a surface-modified metal oxide nanoparticle or colloidally stable metal oxide nanoparticle, preferably said formulation contains a plurality of Nb oxide nanoparticles;
ii) another metal oxide nanoparticle that is not a Nb oxide nanoparticle, preferably said another metal oxide nanoparticle is a surface-modified or colloidally stable metal oxide nanoparticle, preferably said formulation contains a plurality of the another metal oxide nanoparticles; and
iii) a solvent,
wherein said another metal oxide nanoparticle is a TiO₂, ZnO or SnO₂ nanoparticle optionally having one or more surface capping ligands, which can be either chemically bonded to the nanoparticle surface or function as physically interacting additives to enhance stability and performance, optionally, said TiO₂ nanoparticle, ZnO nanoparticle, or SnO₂ nanoparticle are amorphous nanoparticles or crystalline nanoparticles, preferably said another metal oxide nanoparticle is a surface modified TiO₂ nanoparticle having surface capping ligands as a surface modifier;
optionally said Nb oxide nanoparticle is a surface-modified Nb oxide nanoparticle or colloidally stable Nb oxide nanoparticle, having an alkoxysilane as a surface capping ligand or polymerizable functional group, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, preferably said polymerizable functional group is selected from the group consisting of a vinyl group, (meth)acrylic group, epoxy group, a mercapto group, even more preferably said polymerizable functional group is a (meth)acrylic group;
optionally said another metal oxide nanoparticle is a surface-modified or colloidally stable metal oxide nanoparticle having an alkoxysilane as a surface capping ligand or polymerizable functional group, preferably said alkoxysilane is a silane coupling agent or tetraalkoxysilane, more preferably it is a silane coupling agent containing an aliphatic hydrocarbon having at least 4 carbon atoms or aromatic hydrocarbon, polyethylene glycol, and/or a fluorocarbon, preferably said polymerizable functional group is selected from the group consisting of a vinyl group, (meth)acrylic group, epoxy group, a mercapto group, even more preferably said polymerizable functional group is a (meth)acrylic group;
optionally said solvent is an organic solvent, preferably said organic solvent is selected from one or more members of the group consisting of alcohols, glycols, ethers, ketones, esters, hydrocarbons, aromatic hydrocarbons, amides and sulfones. More preferably said organic solvent is selected from one or more members of the group consisting of ethylene glycol monoalkyl ethers, preferably it is ethylene glycol monomethyl ether, ethylene glycol monoethyl ether, ethylene glycol monopropyl ether and/or ethylene glycol monobutyl ether; diethylene glycol dialkyl ethers, preferably it is diethylene glycol dimethyl ether, diethylene glycol diethyl ether, diethylene glycol dipropyl ether and/or diethylene glycol dibutyl ether; propylene glycol monoalkyl ethers, preferably it is propylene glycol monomethyl ether (PGME), propylene glycol monoethyl ether and/or propylene glycol monopropyl ether; ethylene glycol alkyl ether acetates, preferably it is methyl cellosolve acetate and/or ethyl cellosolve acetate; propylene glycol alkyl ether acetates, preferably it is propylene glycol monomethyl ether acetate (PGMEA), propylene glycol monoethyl ether acetate and/or propylene glycol monopropyl ether acetate; 2-(2-butoxyethoxy)ethyl acetate; ketones, preferably it is methyl ethyl ketone, acetone, methyl amyl ketone, methyl isobutyl ketone and/or cyclohexanone; alcohols, preferably it is ethanol, propanol, 1,3-dimethoxy-2-propanol, butanol, hexanol, cyclo hexanol, ethylene glycol, propylene glycol, triethylene glycol, glycerin, pentanols, preferably it is 1-pentanol, 2-pentnol, 3-pentanol, 3-ethyl-3-pentanol, 2,4-dimethyl-3-pentanol; esters, preferably it is ethyl 3-ethoxypropionate, methyl 3-methoxypropionate and/or ethyl lactate; and cyclic esters, preferably it is gamma-butyro-lactone; preferably said solvent is selected from propylene glycol alkyl ether acetates, ethylene glycol monoalkyl ethers, propylene glycol and propylene glycol monoalkyl ethers, 1-pentanol, 2-pentnol, 3-pentanol, 3-ethyl-3-pentanol, 2,4-dimethyl-3-pentanol, 1,3-dimethoxy-2-propanol or a mixture of any one of them.

In a preferred embodiment, said optical gratings of the optical waveguide contains i) Nb oxide nanoparticles;
ii) optionally another metal oxide nanoparticle that is not a Nb oxide nanoparticle, preferably said metal oxide nanoparticle is a surface-modified or colloidally stable metal oxide nanoparticle; and
iv) optionally a matrix material selected from one or more members of the group consisting of a silicone resin, an acrylic resin, an epoxy resin, an olefin resin, a polysulfide resin, a polythiol-urethane resin, polycarbonate resin, a polyamide resin, a polyester resin, a polyphenylene ether resin and a polyarylene sulfide resin, preferably said matrix material is transparent in visible light wavelength, preferably said matrix material is an acrylate resin, an epoxy resin or a mixture of an acrylate resin and an epoxy resin.

According to the present invention, preferably the mass ratio of the another metal oxide nanoparticles to the Nb oxide nanoparticles is within the range from 1:1 to 1:99, preferably it is within the range from 3:7 to 1:49, more preferably from 1:4 to 1:19.

In another embodiment of the present invention, said metal oxide that is placed between said optical gratings of the optical waveguide to fill said optical gratings, is made from a formulation comprising at least;
(i) a metal oxide precursor selected from Tantalum chloride, Tantalum ethoxide, Niobium chloride, niobium ethoxide or an any combination of Tantalum chloride, tantalum ethoxide, Niobium chloride, niobium ethoxide, preferably said any combination is being a combination of Tantalum chloride and Niobium chloride, or a combination of Niobium chloride and Niobium ethoxide.

### Display Device

Finally, the present invention relates to a display device comprising at least one functional medium configured to modulate a light or configured to emit light; and the optical waveguide of the present invention.

Examples of said display device is selected from a Liquid crystal display (LCD), Light emitting diode display (LED display), organic light emitting display (OLED), micro-LED display, quantum dot display (QLED), Augmented Reality (AR) hardware, Virtual Reality (VR) hardware, Mixed Reality (MR) hardware, plasma (PDP) display and an electroluminescent (ELD) display. Said AR, VR and MR hardware are also called as AR, VR and MR display. Preferably said display device is AR hardware, VR hardware or MR hardware.

Thus, the term “functional medium” of the optical device may be LCD, LED, OLED, micro-LED, PDP, ELD layer, array, or display included in said display device.

The present invention is further illustrated by the examples following herein-after which shall in no way be construed as limiting. The skilled person will acknowledge that various modifications, additions and alternations may be made to the invention without departing from the spirit and scope of the invention as defined in the appended claims.

### WORKING EXAMPLES

### Analytics and Measurement Methods

Ellipsometry is used to determine layer thickness, refractive index (n) and absorption index (k) of a metal oxide layer. Measurements are performed using an ellipsometer M2000 from J. A. Woolam and three different angles of incidence (65°, 70° and 75°). The measurement data is analyzed with software CompleteEase from J. A. Woolam, applying a Gen-Osc fitting model for obtaining refractive index (n) as well as absorption index (k). The optical constants are averaged from five measured points on each wafer.

All chemicals for synthesis described are purchased from Sigma Aldrich and used without further purification, unless differently mentioned elsewhere.

UV/vis measurements are performed using a Cary 7000 spectrometer from Agilent. UV LED irradiation is performed by an in-house built 365 LED source.

### Preparation Example 1: Preparation of Surface Modified Ti Oxide Nanoparticle as the Another Metal Oxide Nanoparticle

Heating plate, 2000 mL multi-neck flask with magnetic core, cooler under argon atmosphere is prepared.

98% 3-(Trimethoxysilyl)propyl methacrylate (2.425 mL; 10.00 mmol; 12.500 mol %) is dissolved in 1-methoxypropan-2-ol (1000.000 mL; 10208.50 mmol; 12760.622 mol %) and 2M of hydrochloric acid (HCl) (7760.000 μl; 253.27 mmol; 316.594 mol %) is added. Then obtained solution A is stirred for 2 hours at 80° C. and allowed to cool back to room temperature.

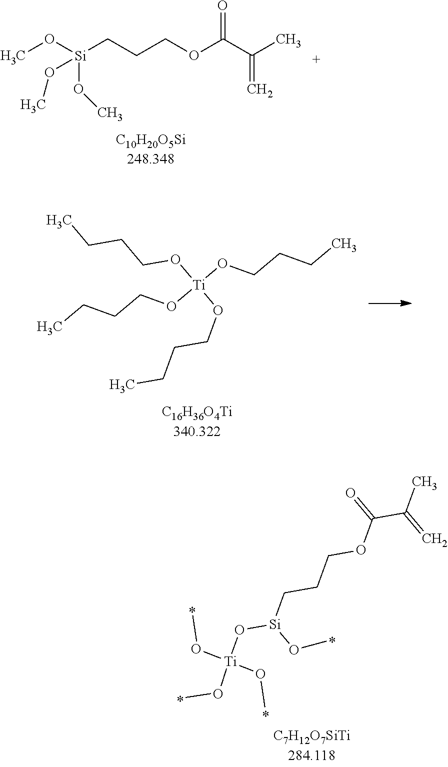

### Preparation Example 2: Preparation of Surface Modified Nb Oxide Nanoparticle

A mixture of Nb₂O₅ nanoparticle and hydrolyzed R—Si(OR′)₃ is prepared based on the procedure of US 2013/016444 A1. Namely based on the following procedure of US 2013/016444 A1.

“1.55 mL of 3-(trimethoxysilyl)propyl methacrylate were added to 650 mL of PGME in a 1 L round bottom flask. 5 mL of 2 M HCl are added and the solution is stirred at room temperature for 20 h. After this, 11.65 mL of niobium ethoxide are added and the solution is heated to 80° C. for 2 h while stirring.

The resulting solution is concentrated by rotor evaporation to 30% w/w.

### Example 1

A 9:1 (Nb₂O₅ nanoparticles:TiO₂ nanoparticles by volume (from preparation examples 1 and 2)) mixture is obtained by mixing the Nb₂O₅ and TiO₂ metal oxide nanoparticle colloids prepared in 1-methoxy-2-propanol as shown in table 1.

Nb₂O₅ nanoparticle colloid: Nb₂O₅ with R—SiO₃ in 1-methoxy-2-propanol where R=prop-3-yl methacrylate, in 1-methoxy-2-propanol TiO₂ nanoparticle colloid: TiO₂ with R—SiO₃ in 1-methoxy-2-propanol wherein R is prop-3-yl methacrylate.

TABLE 1

| M | Nb | Ti |
|---|---|---|
| M:Si ratio | 800 | 800 |
| nanoparticle content | 27 | 23 |
| (mass-%) | | |
| D50 nanoparticle size | 28 | 74 |
| (nm) | | |

### Spin Coating and UV Illumination

PGME solutions of the nanoparticles are obtained by diluting the solutions to the target concentration. Mixtures of Nanoparticles are prepared from the high concentration solutions and then diluted to the final concentration.

Spin coated films are prepared on cleaned two-inch silicon wafers (cleaning procedure: cleaning with 2-propanol, rinsing with deionized water, drying on a hotplate at 100° C. for 10 minutes, plasma cleaning in an oxygen plasma (Diener electronic Femto-SR-PC-c) for 10 minutes) by spin coating 250 μl of a 12 wt % solution of nanoparticles in PGME at 2,000 rpm for 25 seconds with an acceleration of 1,500 rpm/s. The films are soft-baked at 60° C. for 1 minute and illuminated with a UV lamp. After illumination with 365 nm light for 15 minutes (525 mW/cm²), the films are measured with an ellipsometer to determine the refractive index. The results are summarized in the Table 2.

TABLE 2
Refractive index and film thickness of the
films prepared from nanoparticle solutions.

| Nanoparticle | Concentration | Refractive index | Film thickness |
|---|---|---|---|
| solution | [wt %] | @520 nm | [nm] |
| Nb₂O₅ | 12 | 1.888 | 121 |
| nanoparticles in | | | |
| PGME | | | |
| (Formulaiton N1) | | | |
| TiO₂ | 12 | 1.912 | 80 |
| nanoparticles in | | | |
| PGME (ref. 1) | | | |
| Nb₂O₅/ TiO₂ | 12 | 1.899 | 110 |
| nanoparticles | | | |
| (ratio 9:1) | | | |
| Formulation N2 | | | |

By replacing TiO₂ nanoparticles with Nb₂O₅ nanoparticles as the main metal oxide nanoparticles, the issues of photocorrosion associated with TiO₂ can be reduced or eliminated. Furthermore, by incorporating a small amount of TiO₂ nanoparticles, excellent UV photocuring properties can be achieved while allowing for the effective detachment or removal of capping ligands, resulting in the formation of high-quality films with a higher refractive index value.

### NIL Imprint Tests

Formulations for NIL test imprints are prepared by adding ethyl lactate to the high concentration NP solutions in PGME and then removing the PGME under vacuum. The concentration of the NP solution in ethyl lactate is calculated to match the concentrations in PGME.

The high concentration nanoparticle solutions are either diluted with ethyl lactate to the target concentration or the solutions are mixed and the additive (3-(trimethoxysilyl)propyl methacrylate) added and the mixture diluted as a last step to the target concentration.

The composition of the formulations used for NIL imprint tests is shown in Table 3.

TABLE 3
Composition of the solutions for nanoimprint tests.

| | Nb₂O₅ | TiO₂ | | Additive | Ratio | Solvent |
|---|---|---|---|---|---|---|
| | particles | particles | Ratio | concentration | particles/ | concentration |
| | [wt %] | [wt %] | Nb/Ti | [wt %] | additive | [wt %] |
| NIL 1 | 8.64 | 0.96 | 9/1 | 2.4 | 80/20 | 88 |
| NIL 2 (reference | 9.60 | 0 | 1/0 | 2.4 | 80/20 | 88 |
| example) | | | | | | |

Thin films for imprint tests are obtained by spin coating the solutions on cleaned two-inch wafers at 1,000 rpm and letting them dry at room temperature for 10 minutes.

Test structures are imprinted into the films using a commercial NIL tool (NIL Technology CNI v3.0) with a self-made stamp (Ormostamp® on quartz, coated with a Profactor BGL-GZ-96 antisticking layer). Imprints are made by applying reduced pressure to the imprint stack (20 mbar) and applying 4 bar pressure onto the stamp. After a hold time of 4 minutes, the imprints are illuminated at 365 nm for 5 minutes in the tool, followed by an illumination at 365 nm for 15 minutes (525 mW/cm²) outside of the imprint tool. To facilitate SEM analysis, the samples are additionally hardbaked at 300° C. for 5 minutes.

The imprints in NIL 1 have much less cracks and delamination. This is due to a better fixation during the UV illumination step and leads to less defects during the hard baking step. NIL 2 shows significant delamination and stronger cracking during the hard baking step.

### R450/R630 Ratio Measurements Calculated for Each Film Based on its RI at 530 nm

Using the reference formulation (“Ref.1: TiO₂ nanoparticles (Ref.1) is used in the reference formulation as a reference”), multiple optical films were fabricated under varied manufacturing process conditions, each exhibiting a different refractive index at 530 nm. The refractive index across the visible spectrum was measured for each film, and the R450/R630 ratio was calculated for each film based on its RI at 530 nm.

In the same manner, multiple optical films were fabricated with using the formulation N1, Formulation N2, instead of Formulation Ref. 1, under varied manufacturing process conditions, each exhibiting a different refractive index at 530 nm. The refractive index across the visible spectrum was measured for each film, and the R450/R630 ratio was calculated for each film based on its RI at 530 nm.

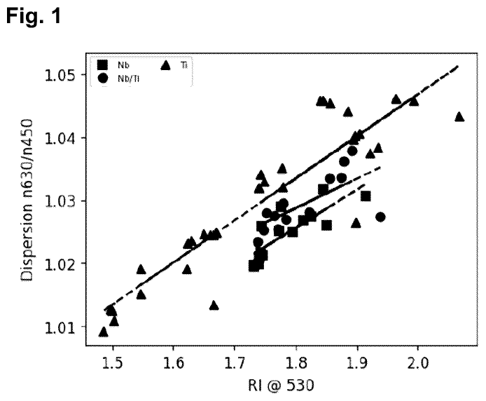

The summary of the dispersion plots from these experiments are shown in FIG. 1. And the films from Formulation N2 (Nb/Ti) has shown the most preferable data. The second is the films from Formulation N1 (Nb). The data shown in FIG. 1 clearly shows that there is an advantage when using Niobium or Nb/Ti hybrid systems when compared to the conventional state of the art approach of using TiO₂ NPs. This is also unexpected when considering the band gap of TiO₂ (3.0-3.2 eV) when compared to Nb₂O₅ (3.0-3.6 eV), since theoretically the larger band gap of Nb₂O₅ should result in larger dispersion in the visible range.

### Comparative Example 1: Gap Filling Formulation to Fill Gaps of Optical Gratings of an Optical Waveguide

First, formulation C1: Ti(OBu)₄(9.6 wt %)_SnCl₂(5.4 wt %)_3-Ethyl-3-pentanol(85 wt %), is prepared by mixing them.

Then with the following process conditions described in Table 4, film samples C1-1 to C1-7 are obtained.

TABLE 4

| | | | Spin | | | Obtained |
|---|---|---|---|---|---|---|
| | | Substrate Pre- | Coating | Hard-bake | Hard-bake | Film |
| Formlation | Substrate | Cleaning | RPM | Temp[° C.] | Time[min] | samples |
| Formulation C1 | Si 2″ | IPA US 10 min | 2,000 | 100 | 5 | C1-1 |
| Formulation C1 | Si 2″ | IPA US 10 min | 2,000 | 150 | 5 | C1-2 |
| Formulation C1 | Si 2″ | IPA US 10 min | 2,000 | 250 | 5 | C1-3 |
| Formulation C1 | Si 2″ | IPA US 10 min | 2,000 | 100 | 5 | C1-4 |
| Formulation C1 | Si 2″ | IPA US 10 min | 2,000 | 150 | 5 | C1-5 |
| Formulation C1 | Si 2″ | IPA US 10 min | 2,000 | 200 | 5 | C1-6 |
| Formulation C1 | Si 2″ | IPA US 10 min | 2,000 | 250 | 5 | C1-7 |

Optical measurements to the obtained samples are performed. The following Table 5 shows the results.

TABLE 5

| | Film | | | | |
|---|---|---|---|---|---|
| Film | thickness | RI at | RI at | RI at | |
| samples | [nm] | 530 nm | 450 nm | 630 nm | R450/R630 |
| C1-1 | 80 | 1.962 | 2.023 | 1.928 | 1.049 |
| C1-2 | 65 | 2.061 | 2.141 | 2.019 | 1.060 |
| C1-3 | 55 | 2.070 | 2.136 | 2.033 | 1.051 |
| C1-4 | 68 | 1.979 | 2.043 | 1.944 | 1.051 |
| C1-5 | 56 | 2.074 | 2.155 | 2.032 | 1.061 |
| C1-6 | 50 | 2.082 | 2.158 | 2.040 | 1.058 |
| C1-7 | 50 | 2.057 | 2.126 | 2.017 | 1.054 |

Within the range from 1.8 to 2.2 at 530 nm, R450/R630 values of the samples are all outside range between 1.015 and 1.045 according to table 5.

### Comparative Example 1: Gap Filling Formulation to Fill Gaps of Optical Gratings of an Optical Waveguide

Formulation C2: SnCl₂(5.5 wt %)_NbCl₅(4.6 wt %)_PGME(90 wt %), is prepared by mixing them.

Then with the following process conditions described in Table 6, film samples C2-1 to C2-6 are prepared.

TABLE 6

| | | Substrate Pre- | Spin Coating | Hard-bake | Hard-bake | Obtained Film |
|---|---|---|---|---|---|---|
| Formlation | Substrate | Cleaning | RPM | Temp[° C.] | Time[min] | samples |
| Formulation C2 | Si 2″ | IPA US 10 min + | 2,500 | 200 | 5 | C2-1 |
| | | Plasma O2 | | | | |
| Formulation C2 | Si 2″ | IPA US 10 min + | 2,500 | 300 | 5 | C2-2 |
| | | Plasma O2 | | | | |
| Formulation C2 | Quartz 2″ | IPA US 10 min + | 2,500 | 200 | 5 | C2-3 |
| | | Plasma O2 | | | | |
| Formulation C2 | Quartz 2″ | IPA US 10 min + | 2,500 | 300 | 5 | C2-4 |
| | | Plasma O2 | | | | |
| Formulation C2 | Si 2″ | IPA US 10 min + | 1,500 | 200 | 5 | C2-5 |
| | | Plasma O2 | | | | |
| Formulation C2 | Si 2″ | IPA US 10 min + | 2,000 | 250 | 13.5 | C2-6 |
| | | Plasma O2 | | | | |

Optical measurements to the obtained samples are performed. The following Table 7 shows the results.

TABLE 7

| | Film | | | | |
|---|---|---|---|---|---|
| Film | thickness | RI at | RI at | RI at | |
| samples | [nm] | 530 nm | 450 nm | 630 nm | R450/R630 |
| C2-1 | 80 | 1.930 | 1.971 | 1.899 | 1.038 |
| C2-2 | 53 | 2.058 | 2.147 | 2.009 | 1.069 |
| C2-3 | 57 | 2.092 | 2.157 | 2.053 | 1.051 |
| C2-4 | 47 | 2.168 | 2.252 | 2.120 | 1.063 |
| C2-5 | 92 | 1.801 | 1.814 | 1.780 | 1.019 |
| C2-6 | 92 | 1.829 | 1.854 | 1.810 | 1.025 |

Within the range from 1.8 to 2.2 at 530 nm, not all R450/R630 values of the samples are within range between 1.015 and 1.045 according to Table 7.

### Working Example: Gap Filling Formulation to Fill Gaps of Optical Gratings of an Optical Waveguide

Formulation W1: NbCl₅(3.7 wt %)_Nb(OEt)₅(6.3 wt %)_1,3-Dimethoxy-2-propanol (hereafter “1;3-DM2P”) (90 wt %), is prepared by mixing them. Then with the following process conditions described in Table 8, film samples W1-1 to W1-7 are prepared.

TABLE 8

| | | | Spin | | | Obtained |
|---|---|---|---|---|---|---|
| | | Substrate Pre- | Coating | Hard-bake | Hard-bake | Film |
| Formlation | Substrate | Cleaning | RPM | Temp[° C.] | Time[min] | samples |
| Formulation | Si 2″ | IPA US 10 min + | 2,500 | 150 | 5 | W1-1 |
| W1 | | Plasma O2 | | | | |
| Formulation | Si 2″ | IPA US 10 min + | 2,500 | 200 | 5 | W1-2 |
| W1 | | Plasma O2 | | | | |
| Formulation | Si 2″ | IPA US 10 min + | 2,500 | 250 | 5 | W1-3 |
| W1 | | Plasma O2 | | | | |
| Formulation | Quartz 2″ | IPA US 10 min + | 2,500 | 100 | 5 | W1-4 |
| W1 | | Plasma O2 | | | | |
| Formulation | Quartz 2″ | IPA US 10 min + | 2,500 | 150 | 5 | W1-5 |
| W1 | | Plasma O2 | | | | |
| Formulation | Quartz 2″ | IPA US 10 min + | 2,500 | 200 | 5 | W1-6 |
| W1 | | Plasma O2 | | | | |
| Formulation | Quartz 2″ | IPA US 10 min + | 2,500 | 250 | 5 | W1-7 |
| W1 | | Plasma O2 | | | | |

IPA US: Isopropyl alcohol with ultrasonification

Optical measurements to the obtained samples are performed. The following Table 9 shows the results.

TABLE 9

| | Film | | | | |
|---|---|---|---|---|---|
| Film | thickness | RI at | RI at | RI at | |
| samples | [nm] | 530 nm | 450 nm | 630 nm | R450/R630 |
| W1-1 | 51 | 1.770 | 1.803 | 1.745 | 1.033 |
| W1-2 | 43 | 1.844 | 1.881 | 1.817 | 1.035 |
| W1-3 | 43 | 1.843 | 1.879 | 1.816 | 1.035 |
| W1-4 | 54 | 1.745 | 1.771 | 1.726 | 1.026 |
| W1-5 | 52 | 1.767 | 1.795 | 1.748 | 1.027 |
| W1-6 | 44 | 1.843 | 1.876 | 1.821 | 1.030 |
| W1-7 | 43 | 1.843 | 1.876 | 1.821 | 1.030 |

All R450/R630 values of the samples are within range between 1.015 and 1.045 according to Table 9.

### Working Example: Gap Filling Formulation to Fill Gaps of Optical Gratings of an Optical Waveguide

Formulation W2: NbCl₅(10.8 wt %)_Nb(OEt)₅(9.2 wt %)_1;3-DM2P(80 wt %), is prepared by mixing them. Then with the following process conditions described in Table 10, film samples W2-1 to W2-8 are prepared.

TABLE 10

| | | | Spin | | | Obtained |
|---|---|---|---|---|---|---|
| | | Substrate Pre- | Coating | Hard-bake | Hard-bake | Film |
| Formlation | Substrate | Cleaning | RPM | Temp[° C.] | Time[min] | samples |
| Formulation | Si 2″ | IPA US 10 min + | 2,500 | 100 | 5 | W2-1 |
| W2 | | Plasma O2 | | | | |
| Formulation | Si 2″ | IPA US 10 min + | 2,500 | 150 | 5 | W2-2 |
| W2 | | Plasma O2 | | | | |
| Formulation | Si 2″ | IPA US 10 min + | 2,500 | 200 | 5 | W2-3 |
| W2 | | Plasma O2 | | | | |
| Formulation | Si 2″ | IPA US 10 min + | 2,500 | 250 | 5 | W2-4 |
| W2 | | Plasma O2 | | | | |
| Formulation | Quartz 2″ | IPA US 10 min + | 2,500 | 100 | 5 | W2-5 |
| W2 | | Plasma O2 | | | | |
| Formulation | Quartz 2″ | IPA US 10 min + | 2,500 | 150 | 5 | W2-6 |
| W2 | | Plasma O2 | | | | |
| Formulation | Quartz 2″ | IPA US 10 min + | 2,500 | 200 | 5 | W2-7 |
| W2 | | Plasma O2 | | | | |
| Formulation | Quartz 2″ | IPA US 10 min + | 2,500 | 250 | 5 | W2-8 |
| W2 | | Plasma O2 | | | | |

Optical measurements to the obtained samples are performed. The following Table 11 shows the results.

TABLE 11

| | Film | | | | |
|---|---|---|---|---|---|
| Film | thickness | RI at | RI at | RI at | |
| samples | [nm] | 530 nm | 450 nm | 630 nm | R450/R630 |
| W2-1 | 181 | 1.743 | 1.770 | 1.727 | 1.025 |
| W2-2 | 142 | 1.767 | 1.796 | 1.747 | 1.028 |
| W2-3 | 123 | 1.827 | 1.859 | 1.806 | 1.029 |
| W2-4 | 113 | 1.862 | 1.896 | 1.839 | 1.031 |
| W2-5 | 155 | 1.730 | 1.756 | 1.711 | 1.026 |
| W2-6 | 137 | 1.768 | 1.802 | 1.746 | 1.032 |
| W2-7 | 121 | 1.818 | 1.854 | 1.795 | 1.033 |
| W2-8 | 116 | 1.843 | 1.877 | 1.820 | 1.031 |

All R450/R630 values of the samples are within range between 1.015 and 1.045 according to Table 11.

### Working Example: Gap Filling Formulation to Fill Gaps of Optical Gratings of an Optical Waveguide

Formulation W3: NbCl₅(5.7 wt %)_TaCl₅(4.3 wt %)_PGME(90 wt %), is prepared by mixing them. Then with the following process conditions described in Table 12, film samples W3-1 to W3-9 are prepared.

TABLE 12

| | | | Spin | | | Obtained |
|---|---|---|---|---|---|---|
| | | Substrate Pre- | Coating | Hard-bake | Hard-bake | Film |
| Formlation | Substrate | Cleaning | RPM | Temp[° C.] | Time[min] | samples |
| Formulation W3 | Si 2″ | IPA US 10 min | 3,000 | 200 | 5 | W2-1 |
| Formulation W3 | Si 2″ | IPA US 10 min | 3,000 | 200 | 5 | W2-2 |
| Formulation W3 | Si 2″ | IPA US 10 min | 2,000 | 100 | 5 | W2-3 |
| Formulation W3 | Si 2″ | IPA US 10 min | 2,000 | 150 | 5 | W2-4 |
| Formulation W3 | Si 2″ | IPA US 10 min | 2,000 | 200 | 5 | W2-5 |
| Formulation W3 | Si 2″ | IPA US 10 min | 2,000 | 250 | 5 | W2-6 |
| Formulation W3 | Si 2″ | IPA US 10 min | 2,000 | 100 | 5 | W2-7 |
| Formulation W3 | Si 2″ | IPA US 10 min | 2,000 | 150 | 5 | W2-8 |
| Formulation W3 | Si 2″ | IPA US 10 min | 2,000 | 200 | 5 | W2-9 |

Optical measurements to the obtained samples are performed. The following Table 13 shows the results.

### Table 13:

All R450/R630 values of the samples are within range between 1.015 and 1.045 according to Table 13.

TABLE 13

| | Film | | | | |
|---|---|---|---|---|---|
| Film | thickness | RI at | RI at | RI at | |
| samples | [nm] | 530 nm | 450 nm | 630 nm | R450/R630 |
| W2-1 | 101 | 2.045 | 2.092 | 2.015 | 1.038 |
| W2-2 | 92 | 1.708 | 1.729 | 1.694 | 1.021 |
| W2-3 | 140 | 1.896 | 1.928 | 1.874 | 1.029 |
| W2-4 | 136 | 1.946 | 1.983 | 1.921 | 1.032 |
| W2-5 | 113 | 2.013 | 2.055 | 1.985 | 1.036 |
| W2-6 | 106 | 2.086 | 2.124 | 2.051 | 1.036 |
| W2-7 | 133 | 1.919 | 1.956 | 1.894 | 1.033 |
| W2-8 | 125 | 1.967 | 2.006 | 1.942 | 1.033 |
| W2-9 | 120 | 2.02 | 2.06 | 1.993 | 1.033 |

All R450/R630 values of the samples are within range between 1.015 and 1.045 according to Table 13.

1. A method for fabricating an optical waveguide comprising following steps (A) to (D),
(A) Selecting metal oxide precursor materials, or mixtures of metal oxide precursor materials, such that even when multiple cured films are produced separately and exhibit differing refractive index (RI) values at 530 nm within the range of 1.7 to 2.3, the ratio of the refractive index at 450 nm (R450) to that at 630 nm (R630) consistently remains between 1.015 and 1.045;
(B) preparing a formulation containing the selected metal oxide precursor material or the mixture of the metal oxide precursor materials;
(C) providing the formulation obtained in step (B) over a surface of a substrate to form a curable composite; and
(D) curing the formulation to obtain a cured composite.

2. The method of claim 1, wherein said substrate contains optical gratings on the surface and said cured composite fills at least some of the gaps in the optical gratings.

3. The method of claim 1, wherein said cured composite obtained in step (D) is being one or more of optical gratings of the optical waveguide, and
wherein following step (E) is applied before step (D) after step (C), and step (D) consists of following steps (D1) and (F) to form said optical gratings:
(E) pressing a mold against said curable composite formed on the substrate;
(D1) irradiating the curable composite with UV light to form the cured composite; and
(F) optionally applying a thermal treatment to remove any organic component, and
optionally in step (F), the temperature of the thermal treatment in the range from 50 to 650° C. is applied,
optionally, in step (F), a UV cured composite obtained by step (D1) is heated from the room temperature to the temperature in the range from 200 to 600° C.

4. The method of claim 2, wherein said formulation comprises at least:
(i) a metal oxide precursor material selected from Tantalum chloride, Tantalum ethoxide, Niobium chloride, niobium ethoxide or an any combination of Tantalum chloride, Tantalum ethoxide, Niobium chloride, niobium ethoxide.

5. The method of claim 3, wherein said formulation comprises at least:
i) a Nb oxide nanoparticle as a metal oxide precursor material;
ii) optionally another metal oxide nanoparticle that is not a Nb oxide nanoparticle; and
iii) a solvent,
wherein said another metal oxide nanoparticle comprises a metal element selected from the group consisting of group 4 elements of the periodic table, group 12 elements of the periodic table, or group 14 elements of the periodic table;
optionally said Nb oxide nanoparticle is a surface-modified Nb oxide nanoparticle or colloidally stable Nb oxide nanoparticle, having an alkoxysilane as a surface capping ligand or polymerizable functional group;
optionally said another metal oxide nanoparticle is a surface-modified or colloidally stable metal oxide nanoparticle having an alkoxysilane as a surface capping ligand or polymerizable functional group;
optionally said solvent is an organic solvent.

6. The method of claim 3, wherein said formulation comprises at least a mixture of metal oxide precursor materials of:
i) a Nb oxide nanoparticle, preferably said Nb oxide nanoparticle is a surface-modified metal oxide nanoparticle or colloidally stable metal oxide nanoparticle; and
ii) another metal oxide nanoparticle that is not a Nb oxide nanoparticle, preferably said metal oxide nanoparticle is a surface-modified or colloidally stable metal oxide nanoparticle;
wherein the formulation further comprises
iii) a solvent,
wherein said another metal oxide nanoparticle is a TiO₂, ZnO or SnO₂ nanoparticle optionally having one or more surface capping ligands, which can be either chemically bonded to the nanoparticle surface or function as physically interacting additives to enhance stability and performance, optionally, said TiO₂ nanoparticle, ZnO nanoparticle, or SnO₂ nanoparticle are amorphous nanoparticles or crystalline nanoparticles;
optionally said Nb oxide nanoparticle is a surface-modified Nb oxide nanoparticle or colloidally stable Nb oxide nanoparticle, having an alkoxysilane as a surface capping ligand or polymerizable functional group;
optionally said another metal oxide nanoparticle is a surface-modified or colloidally stable metal oxide nanoparticle having an alkoxysilane as a surface capping ligand or polymerizable functional group;
optionally said solvent is an organic solvent.

7. The method of claim 3, wherein the mass ration of the another metal oxide nanoparticles to the Nb oxide nanoparticles is within the range from 1:1 to 1:99.

8. An optical waveguide comprising one or more of optical gratings and optionally said one or more optical gratings is at least partly filled with a metal oxide; wherein
1) said optical gratings have a refractive index value at 530 nm within the range of 1.7 to 2.3, and the ratio of the refractive index at 450 nm (R450) to the refractive index at 630 nm (R630) is between 1.015 and 1.045; and/or
2) one or more optical gratings is at least partly filled with a metal oxide and said metal oxide has a refractive index value at 530 nm falls within the range of 1.7 to 2.3, and the ratio of the refractive index at 450 nm (R450) to the refractive index at 630 nm (R630) is between 1.015 and 1.045.

9. An optical waveguide obtained by the method of claim 1, wherein:
1) said optical gratings have a refractive index value at 530 nm within the range of 1.7 to 2.3, and the ratio of the refractive index at 450 nm (R450) to the refractive index at 630 nm (R630) is between 1.015 and 1.045; and/or
2) one or more optical gratings is at least partly filled with a metal oxide and said metal oxide has a refractive index value at 530 nm within the range of 1.7 to 2.3, and the ratio of the refractive index at 450 nm (R450) to the refractive index at 630 nm (R630) is between 1.015 and 1.045.

10. The optical waveguide of claim 9, wherein said optical gratings are made from the formulation comprising at least:
i) a Nb oxide nanoparticle;
ii) optionally another metal oxide nanoparticle that is not a Nb oxide nanoparticle; and
iii) a solvent;
wherein said another metal oxide nanoparticle comprises a metal element selected from the group consisting of group 4 elements of the periodic table, group 12 elements of the periodic table, group 14 elements of the periodic table;
optionally said Nb oxide nanoparticle is a surface-modified Nb oxide nanoparticle or colloidally stable Nb oxide nanoparticle, having an alkoxysilane as a surface capping ligand or polymerizable functional group;
optionally said another metal oxide nanoparticle is a surface-modified or colloidally stable metal oxide nanoparticle having an alkoxysilane as a surface capping ligand or polymerizable functional group; and
optionally said solvent is an organic solvent.

11. The optical waveguide of claim 10,
wherein said another metal oxide nanoparticle is a TiO₂, ZnO or SnO₂ nanoparticle optionally having one or more surface capping ligands, which can be either chemically bonded to the nanoparticle surface or function as physically interacting additives to enhance stability and performance, optionally, said TiO₂ nanoparticle, ZnO nanoparticle, or SnO₂ nanoparticle are amorphous nanoparticles or crystalline nanoparticles.

12. The optical waveguide of claim 8, wherein said optical gratings contains i) Nb oxide nanoparticles;
ii) optionally another metal oxide nanoparticle that is not a Nb oxide nanoparticle, optionally said another metal oxide nanoparticle is a surface-modified or colloidally stable metal oxide nanoparticle; and
iv) optionally a matrix material selected from one or more members of the group consisting of a silicone resin, an acrylic resin, an epoxy resin, an olefin resin, a polysulfide resin, a polythiol-urethane resin, polycarbonate resin, a polyamide resin, a polyester resin, a polyphenylene ether resin and a polyarylene sulfide resin, optionally said matrix material is transparent in visible light wavelength.

13. The optical waveguide of claim 8, wherein the mass ratio of the another metal oxide nanoparticles to the Nb oxide nanoparticles is within the range from 1:1 to 1:99.

14. The optical waveguide of claim 8, wherein said metal oxide that is placed between said optical gratings to fill said optical gratings is made from a formulation comprising at least:
(i) a metal oxide precursor selected from Tantalum chloride, Niobium chloride, niobium ethoxide or an any combination of Tantalum chloride, Niobium chloride, and niobium ethoxide.

15. A display device comprising at least one functional medium configured to direct and modulate a light or configured to emit light; and the optical waveguide of claim 8.

16. The method of claim 1, wherein in step (A), the metal oxide precursor materials, or mixtures of metal oxide precursor materials, are selected such that even when multiple cured films are produced separately and exhibit differing refractive index (RI) values at 530 nm within the range 1.8 to 2.2, the ratio of the refractive index at 450 nm (R450) to that at 630 nm (R630) consistently remains between 1.015 and 1.040.

17. The method of claim 1, wherein in step (C), the formulation obtained in step (B) is provided over the surface of the substrate by spin-coating or ink-jetting.

18. The method of claim 1, wherein in step (D), the formulation is cured by heat and/or by UV irradiation.

19. The method of claim 3, wherein the UV light has a wavelength around 365 nm.
